(19) United States
(12) Patent Application Publication
(10) Pub. No.: US 2026/0185210 A1
(43) Pub. Date: Jul. 2, 2026

(54) APPARATUS AND METHOD FOR DEPOSITING SUBLIMATED MATRIX TO A SUBSTRATE

(71) Applicant: TECHNISCHE UNIVERSITÄT WIEN, Wien (AT)

(72) Inventors: Martina Marchetti-Deschmann, Vienna (AT); Martin Handelshauser, Vienna (AT); Mathis Nalbach, Vienna (AT); Philipp Thurner, Vienna (AT); Peter Sandbichler, Vienna (AT)

(21) Appl. No.: 19/130,290

(22) PCT Filed: Nov. 18, 2022
(86) PCT No.: PCT/AT2022/060404

§ 371 Date: May 15, 2025

(51) Int. Cl. C23C 14/24; C23C 14/50; C23C 14/54

(52) U.S. Cl. CPC C23C 14/243; C23C 14/50; C23C 14/541

(57) ABSTRACT

The invention relates to an apparatus for depositing sublimated matrix (1) to a substrate (2) comprised of a sublimation chamber (3) with a pressure adjustment unit (4) adapted to adjust the gas pressure (pᵥ) inside the sublimation chamber (3), a substrate holder (5), and a matrix container (6) being arranged at a distance from the substrate holder (5), wherein the substrate holder (5) and the matrix container (6) are arranged within the sublimation chamber (3), wherein the substrate holder (5) comprises a cooling unit (7) adapted to apply a predetermined temperature (Tₛ) to the substrate (2), and wherein the matrix container (6) comprises a heating unit (8) adapted to apply a predetermined temperature (Tₘ) to the matrix (1), wherein the apparatus comprises a gas supply unit (9) adapted to introduce a stream of heated gas at a temperature (T_{g}) of above 50° C., preferably of above 100° C., into the sublimation chamber (3). The invention further relates to a method.

The invention relates to an apparatus and a method for depositing a sublimated matrix material to a substrate with the features of the independent patent claims.

Matrix-assisted laser desorption ionization mass spectrometry imaging (MALDI-MSI) is a powerful tool for directly visualizing the distribution of a variety of molecules in biological tissues. Today, MALDI-MSI is used for mapping a wide range of biomolecules including metabolites, lipids, carbohydrates, peptides, and proteins from thin tissue sections in precise correlation with histology for numerous applications ranging from developmental biology, pharmacology, phytology, forensics, and understanding the onset and progression of disease. MALDI-MSI is now recognized as an important and indispensable analytical tool in the ongoing pursuit of understanding life and disease.

An important aspect to obtain high-quality results when working with MALDI-MSI is the sample preparation process, as for the proper functioning of this analysis method it is necessary to provide a so-called matrix together with the sample material which matrix is excitable by means of the laser of the mass spectrometric device used for sample irradiation.

Among various methods for sample preparation, it is known to deposit a layer of matrix material to a sample's surface via a matrix sublimation apparatus. This approach has proven to be particularly suitable for MALDI-MSI due to limited risk of analyte de-localization during the sample preparation process. Commercial solutions for this purpose are known in the art. Additionally, custom-built solutions are common in research laboratories.

However, apparatuses known to date often lack in user-friendliness, safety of use, as well as quality and reproducibility of the deposited matrix layers. One particular problem of the currently known apparatuses is a lack of uniform and reproducible sample preparation, resulting in highly user-dependent matrix deposition characteristics and therefore varying MALDI-MSI results. Additionally, variations of the matrix deposition conditions may lead to high variations in the quality of the produced matrix layers.

Due to this fact, users of such apparatuses usually have to be highly trained or very experienced, such that reliable MALDI-MSI results can be obtained. Therefore, improvements in relation to these aspects would be necessary to achieve broader applicability of MALDI-MSI in medicine and analytical chemistry.

The invention therefore particularly relates to an apparatus for depositing sublimated matrix to a substrate, the apparatus comprising a sublimation chamber with a pressure adjustment unit adapted to adjust the gas pressure inside the sublimation chamber; a substrate holder; and a heating unit comprising a matrix container. The matrix container may be arranged at a distance to the substrate holder. The substrate holder and the matrix container are particularly arranged within the sublimation chamber. The substrate holder particularly comprises a cooling unit adapted to apply a predetermined temperature to the substrate, and the heating unit particularly is adapted to apply a predetermined temperature to the matrix. A control device may be provided which is operably connected to at least the pressure adjustment unit (4), to the heating unit (7), and to the cooling unit (8).

An object of the present invention can therefore be seen in providing an apparatus for depositing sublimated matrix to a substrate, which allows the production of matrix layers with high reproducibility and uniformity. A particular object of the present invention can be seen in providing a simplified and/or at least partly automated matrix deposition process. A specific object may be seen in providing and apparatus that is suitable for the production of high-quality matrix layers on samples for MALDI-MSI analysis.

Is has been found in the course of making the present invention that at least one of the above-mentioned objects can particularly be solved by optionally providing a gas supply unit adapted to introduce a stream of heated gas at a temperature of above 50° C., preferably of above 100° C., into the sublimation chamber.

This feature specifically allows recrystallizing the matrix material after its deposition on the substrate, ultimately leading to a highly uniform matrix layer.

The gas supply unit may as well be operably connected to the control device.

When the apparatus is used in the course of sample preparation for MALDI-MSI analysis, the matrix is typically a material that is excitable by the laser of the mass spectrometric device. Such materials are well known in the art and include but are not limited to sinapinic acid, α-cyano-4-hydroxycinnamic acid α-CHCA), and 2,5-dihydroxybenzoic acid (DHB). When used for MALDI-MSI analysis, the substrate typically has a flat surface carrying a sample, such as a tissue thin-section. The substrate may particularly be a microscopic slide, optionally having a coating on its surface, such as a coating of indium tin oxide.

However, it has to be mentioned that the apparatus of the invention cannot only be used for the purpose of sample preparation for MALDI-MSI, but also for other purposes where a sublimated material is deposited to a surface. Therefore, the term “matrix” is not specifically limited, as long as the matrix can be sublimated at the conditions (i.e., in particular temperature and pressure) provided by the apparatus or present within the sublimation chamber. Also the term “substrate” is not specifically limited as long as the sublimated matrix can be deposited (i.e., re-sublimated) at least on a part of the substrate's surface. The substrate surface does not necessarily have to be flat.

Apart from sample preparation for MALDI-MSI, the apparatus of the present invention can for example also be beneficially used in the production of coatings in material production. In this context, the advantageous effects of the inventive apparatus can be similarly exploited.

Optionally, the apparatus further comprises a vapor generation unit adapted to introduce a vaporized substance, in particular an acidic substance into the sublimation chamber. The vapor generation unit may particularly be heatable for this purpose.

The introduction of a vaporized substance into the sublimation chamber is advantageous for promoting the recrystallization of the matrix that has been deposited onto the substrate. Acidic substances are preferably used as vaporized substances.

Preferably, the vapor generation unit is heatable by means of the same heating unit that is also used to apply a predetermined temperature to the matrix. In this case, the apparatus matrix container and the vapor generation unit may be interchangeable. In particular, the heating unit may comprise a recess into which the matrix container and the vapor generation unit can be interchangeably inserted. The vapor generation unit may also be a liquid container.

This embodiment is advantageous due to facilitating the sublimation and subsequent recrystallization in the very same apparatus via simply exchanging the matrix container by the vapor generation unit.

In an alternative embodiment, the apparatus can comprise a second heating unit that is used for heating the vapor generation unit. In this case, no exchange of matrix container and vapor generation unit is necessary in order to initiate the recrystallization process and the sample preparation process including matrix deposition and recrystallization can be completely independent form manual influence.

Optionally a shutter can be provided being adapted to be switched between a first position and a second position. In its first position the shutter may be adapted to prevent matrix from being deposited on the substrate, and in its second position the shutter may allow matrix to be deposited on the substrate. In particular, the shutter may act as an opening/closing mechanism for the matrix container. Additionally, sealing means may be provided in order to avoid matrix to escape when the shutter is closed.

The possibility of switching the shutter between a first and second position is advantageous in that it enables depositing sublimated matrix and introduction of a vaporized substance into the sublimation chamber at a desired point in time. In particular, the shutter can aid in improving the homogeneity of the deposited matrix layer as the deposition process can be initiated in a controlled manner, for example after the predetermined temperature has been reached and the sublimation system is in an equilibrium state.

If a second recess for accommodating the vacuum generation unit is provided, as described above, the shutter may be adapted to separately cover/uncover each of the recesses.

Optionally, the shutter in its first position substantially completely covers the recess of the heating unit. This feature allows to substantially completely prevent contact of already sublimated matrix with the substrate, for example during heating the matrix to the predetermined temperature and/or during an equilibration phase. This allows a further optimization of the properties of the deposited matrix layer.

Optionally, a control device may be provided, which is operably connected to the pressure adjustment unit, to the heating unit, and to the cooling unit, wherein the control device is adapted to adjust the gas pressure inside the sublimation chamber, as well as the temperature applied to the matrix and the temperature applied to the substrate on the basis of a correlation table or on the basis of entries of a correlation table. This correlation table may contain a predetermined list of matrices, wherein each matrix in the correlation table is assigned with a sublimation chamber pressure, matrix temperature and substrate temperature.

Unexperienced users without extensive prior knowledge are therefore capable of operating the apparatus. In particular, the users do not need to have knowledge about the optimal parameters for matrix sublimation and deposition, and it can be made sure that the applied parameters are the same for every deposition process. Providing this feature can also solve at least one of the objects of the invention that have been described above.

The values contained in the correlation table may be evaluated by empirical testing or based on literature values. The correlation table may be stored in a data storage unit of the control device. The correlation table may contain at least two entries with different matrices along with the correlating sublimation chamber pressure, matrix temperature and substrate temperature.

A control device with an input unit may be provided, where a matrix material contained in the correlation table can be selected. The input unit may for example be a computer with a graphical interface.

Optionally, the control device may be operably connected to the shutter. This feature may enable controlling the shutter position via the control device, further improving operability of the apparatus.

Optionally, a pressure sensor may be provided in the sublimation chamber, which is operably connected to the control device, such that a closed-loop control of the gas pressure inside the sublimation chamber can be performed. Using a closed-loop control of pressure, it can be made sure that the correct sublimation pressure is set within the sublimation chamber. This may particularly improve reproducibility of the deposited matrix.

Optionally, a matrix temperature sensor may be provided which is adapted to measure the temperature of the matrix and which sensor operably connected to the control device, such that a closed-loop control of the matrix temperature can be performed.

Using a closed-loop control of temperature, it can be made sure that the correct sublimation temperature is applied to the matrix. This may particularly improve reproducibility of the deposited matrix layers. Additionally, it may be verified that matrix is actually being sublimated.

Optionally, a substrate temperature sensor may be provided which is adapted to measure the temperature of the substrate and which sensor is operably connected to the control device, such that a closed-loop control of the substrate temperature can be performed. Using a closed-loop control of temperature, it can be made sure that the substrate has the desired re-sublimation temperature. This may particularly improve reproducibility of the deposited matrix layers and ensure that the matrix is actually deposited on the substrate.

Optionally, the distance between the substrate holder and the matrix container may be adjustable. Said distance may particularly be adjustable by means of a drive unit, such as a drive motor. Since different matrices may require different preparation conditions, adjustability of said distance may be beneficial to set the optimal distance between the substrate and the matrix container.

Optionally, the drive unit may be operably connected to the control device. Additionally, each matrix in the correlation table may additionally be assigned with a distance, such that the distance between matrix and substrate can be adjusted based on the correlation table. This feature allows for a simple way of setting the distance, wherein the preferred values contained in the correlation table can for example be determined empirically.

Optionally, also the gas supply unit may be operably connected to the control device, wherein each matrix in the correlation table is additionally assigned with a temperature of the heated gas, and wherein the temperature of the heated gas is adjusted based on the entries of the correlation table. This feature allows for a simple way of adjusting the temperature of the heated gas.

The present invention also relates to a method for depositing a sublimated matrix to a substrate. The method may comprise the step of positioning the matrix and the substrate at a distance from each other in a sublimation chamber.

The method may further comprise the step of controlling and/or setting the gas pressure inside the sublimation chamber to a first gas pressure level, wherein the first gas pressure level is below atmospheric pressure. The first gas pressure is particularly a pressure at which the matrix can be sublimated.

The method may further comprise the step of heating the matrix to a predetermined matrix temperature and cooling the substrate to a predetermined substrate temperature, wherein the matrix temperature is above the matrix sublimation point at the first gas pressure level, and wherein the substrate temperature is below the matrix material sublimation point at the first gas pressure level, such that at least part of the matrix is sublimated and subsequently re-sublimated on the substrate.

The method may further comprise the step of introducing a stream of heated gas at a temperature of above 50° C., preferably of above 100° C., into the sublimation chamber.

The method according to the invention also solves at least one of the objects of the invention that have been described in connection with the inventive apparatus.

Optionally, the method may additionally comprise the step of introducing a vaporized substance into the sublimation chamber. The vaporized substance may be an acidic substance.

Optionally, the matrix temperature during sublimation of the matrix is between 100° C. and 200° C. Optionally, the substrate temperature during deposition of the sublimated matrix is between 0° C. and 30° C., preferably between 10° C. and 20° C.

Optionally, the first gas pressure is below 200 mbar.

Optionally, the gas pressure inside the sublimation chamber during the step of introducing a stream of heated gas into the sublimation chamber is controlled to a second gas pressure, wherein the second gas pressure is between 900 mbar and 1100 mbar, preferably atmospheric pressure.

Optionally, sublimated matrix may be prevented from being deposited on the substrate during an equilibration phase, wherein during the equilibration phase the matrix is heated to and/or kept at the predetermined matrix temperature. The equilibration phase is particularly beneficial to obtain a constant sublimation regime. During the equilibration phase the shutter of the apparatus may be in its first, i.e., closed, position.

Optionally, the equilibration phase may be followed by a deposition phase, wherein in the deposition phase sublimated matrix is allowed to be deposited on the substrate, and wherein the first gas pressure, the matrix temperature, and the substrate temperature are substantially constant during the deposition phase. During the deposition phase, the shutter of the apparatus may be in is second, i.e., open, position Optionally, sublimated matrix may be allowed to be deposited on the substrate for at least 5 min, preferably for between 10 min to 60 min.

Further features according to the invention can be derived from the patent claims, the description of the exemplary embodiments, as well as the appended drawings.

In the following, certain features and effects of the present invention are described by making reference to exemplary embodiments of the invention. The embodiments are solely used for illustrative purposes and are not intended to restrict the scope of the invention which is determined by the independent patent claims.

In the drawings:

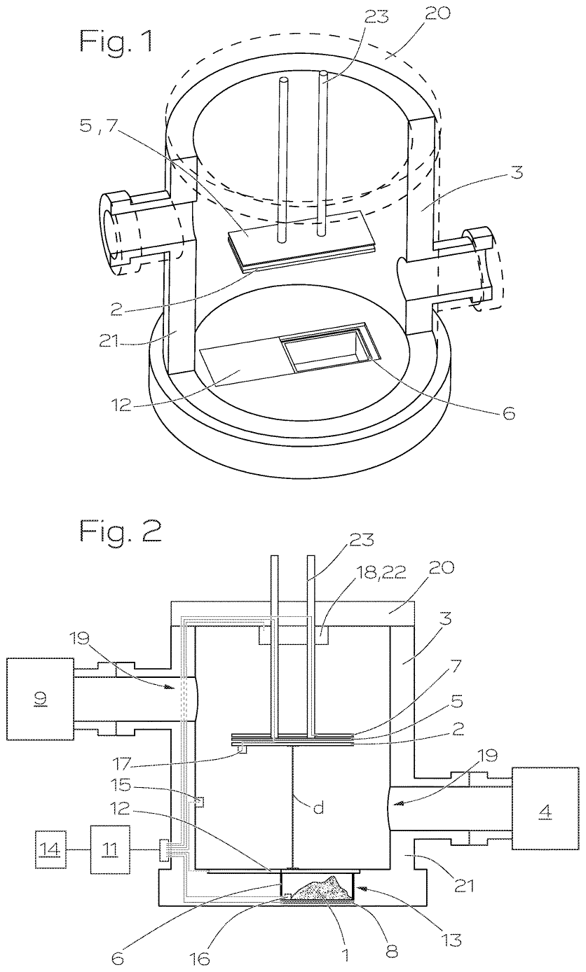

FIG. 1 shows a schematic isometric view of an apparatus according to a first exemplary embodiment of the present invention;

FIG. 2 shows a schematic cross sectional view of the first embodiment;

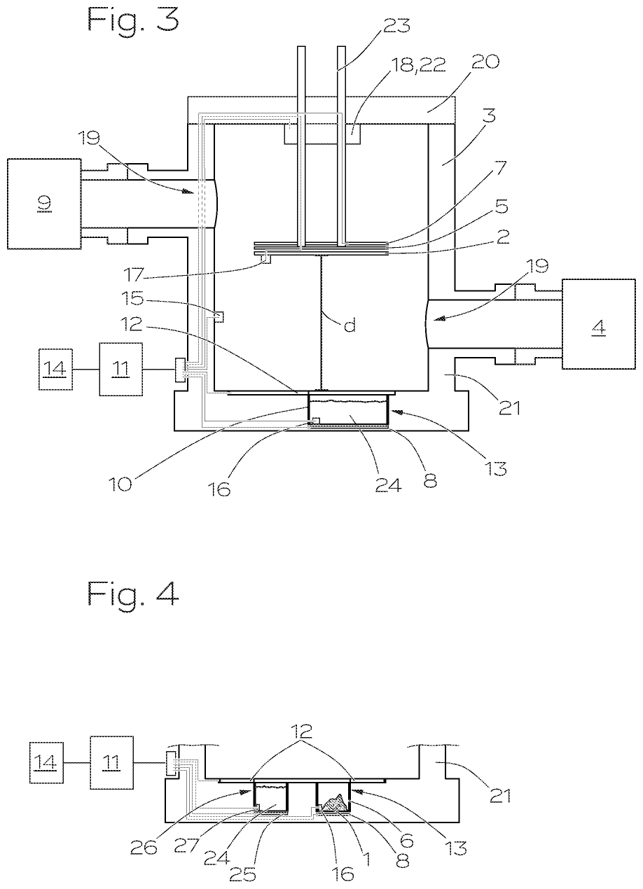

FIG. 3 shows another schematic cross sectional view of the first embodiment; and

FIG. 4 shows a schematic cross sectional view of the bottom part of an apparatus according to a second exemplary embodiment of the present invention.

FIG. 1 shows a schematic isometric view of an apparatus according to a first exemplary embodiment of the present invention. FIGS. 2 and 3 show schematic cross sectional views of the first embodiment of the apparatus shown in FIG. 1.

The apparatus according to the first embodiment will be described by making reference to FIGS. 1 to 3 for sake of clarity and conciseness. The apparatus comprises a sublimation chamber 3 with a pressure adjustment unit 4, wherein the pressure adjustment unit 4 is adapted to adjust the gas pressure pₛ inside the sublimation chamber 3. In this embodiment, the pressure adjustment unit 4 comprises a vacuum pump, which is adapted to generate a vacuum of a pressure of 200 mbar and below.

As can be seen in the drawings, the apparatus comprises a substrate holder 5 and a matrix container 6. The matrix container 6 is arranged at a distance from the substrate holder 5. The substrate holder 5 and the matrix container 6 are both arranged within the sublimation chamber 3.

The substrate holder 5 comprises a cooling unit 7, which is a Peltier cooling element having a substantially flat surface, adapted to accommodate a substantially flat substrate 2, such as a microscopic slide. The cooling unit 7 of the present embodiment is adapted to apply a predetermined temperature Tₛ to the substrate 2, which temperature is between approximately −10° C. and 20° C. In any case, the temperature Tₛ will be set in dependence of the matrix 1 to be deposited. In order to achieve deposition of the matrix 1 on the substrate 2, the temperature Tₛ will need to be at or below the sublimation temperature of the matrix 1.

As can be seen in FIGS. 2 and 3, the substrate holder 5 with the substrate attached thereto is connected to a drive unit 18, in order to change the position of the substrate 2 with respect to the matrix container 6. In other words, the drive unit 18 can be used to adapt the distance d between substrate 2 and matrix 1. The drive unit 18 comprises a motor unit 22 as well as drive rods 23, which carry the substrate holder 5.

The matrix container 6 comprises a heating unit 8 adapted to apply a predetermined temperature Tₘ to the matrix 1. The predetermined temperature can be between approximately 100° C. and 200° C., but it will need to be adjusted in dependence on the matrix 1 and the gas pressure pₛ. In particular, the temperature Tₘ is required to be above the sublimation temperature of the matrix 1, such that gaseous matrix material can be obtained, which subsequently can be deposited on the substrate 2.

The apparatus further comprises a gas supply unit 9 adapted to introduce a stream of heated gas at a temperature T_{g} of above 50° C., preferably of above 100° C., into the sublimation chamber 3. In the present embodiment, the gas supply unit 9 comprises a fan combined with an air heater, such that heated air can be introduced into the sublimation chamber 3.

The pressure adjustment unit 4 and the gas supply unit 9 are connected to the sublimation chamber 3 via openings 19 that ware formed in the wall of the sublimation chamber 3. The substrate holder 5 with the cooling unit 7 and the drive unit 18 are held on a removable lid 20, which lid 20 can be sealingly connected with the chamber body 21 in order to form the substantially gas-tight sublimation chamber 3.

The bottom of the chamber body 21 comprises a recess 13, which is adapted to accommodate the matrix container 6, as particularly illustrated in FIG. 2. The recess 13 may also accommodate the vapor generation unit 10, as illustrated in FIG. 3, wherein matrix container 6 and vapor generation unit 10 can be interchangeably inserted into the recess 13.

The matrix container 6 and vapor generation unit 10 being inserted into the recess 13 can be heated by a heating unit 8. The heating unit 8 is adapted to be set to a temperature between 100° C. and 200° C. However, the exact temperature will be set in dependence of the sublimation temperature of the matrix 1 or the temperature required for generating vapor via the vapor generation unit 10.

The recess 13 can be closed by a shutter 12, which is slideable between an open position and a closed position. In FIG. 1, the shutter 12 completely reveals the recess 13, i.e., the shutter 12 is in a completely open position. The open position allows sublimated matrix 1 to be deposited on the substrate 2, whereas in the closed position it prevents sublimated matrix 1 from escaping the recess 13.

The vapor generation unit 10 is adapted to introduce a vaporized substance into the sublimation chamber 3. The vaporized substance can be an acidic substance, such as an acidic liquid.

The apparatus additionally comprises a control device 11 which is operably connected to multiple parts of the apparatus, namely the pressure adjustment unit 4, the heating unit 7, the cooling unit 8, the shutter 12, as well as the drive unit 18.

In order to allow a closed-loop control of the parameters set by the different control elements, sensors are provided, which are also operably connected to the control device 11. Said sensors are particularly a pressure sensor 15, a matrix temperature sensor 16, and a substrate temperature sensor 17.

The pressure sensor 15 is adapted to measure the gas pressure inside the sublimation chamber 3. The matrix temperature sensor 16 is adapted to measure the temperature applied to the matrix 1. The substrate temperature sensor 17 is adapted to measure the temperature of the substrate 2.

The control device 11 is adapted to adjust the gas pressure pₛ inside the sublimation chamber 3, the temperature Tₘ applied to the matrix 1 and the temperature Tₛ applied to the substrate 2. A closed-loop control of these parameters is performed based on the feedback of the above-mentioned sensors 15, 16, 17.

A correlation table which contains a predetermined list of matrices M₁, M₂, . . . , Mₙ is stored on a storage unit of the control unit 11. In the correlation table, each matrix M₁, M₂, . . . , Mₙ is assigned with a corresponding sublimation chamber pressure p_{s,1}, p_{s,2}, . . . , p_{s,n}, matrix temperature T_{m,1}, T_{m,2}, . . . , T_{m,n}, and substrate temperature T_{s,1}, T_{s,2}, . . . , T_{s,n}.

The correlation table also contains matrix-dependent information on the substrate-to-matrix distance d and the temperature of the heated gas T_{g} which is introduced via the gas supply unit 9.

The control device 11 comprises an input unit 14, which is equipped with a graphical input interface, on which at least the matrix material currently used can be selected from the entries of the correlation table.

It shall be mentioned that the pressure adjustment unit 4, the gas supply unit 9, and the control device 11 with its input unit 14 are not depicted in FIG. 1 for the sake of clarity.

In the following, an exemplary method for depositing matrix 1 on a substrate 2 using the apparatus according to the first embodiment will be described in detail.

A biological sample, e.g. skin, is cryo- or microsectioned and mounted onto an indium tin oxide-coated microscopic glass slide. Said glass slide serves as the substrate 2, where matrix 1 is to be deposited.

The substrate 2 is mounted onto the substrate holder 5 via adhesive copper tape. Matrix 1 is filled into the matrix container 6, which is placed in the recess 13. The shutter 12 is brought into the closed position; the lid 20 of the sublimation chamber 3 is closed.

In this exemplary method, the matrix 1 is 1,5-Diaminonaphthalene.

The software stored on the control device 11 is started via the input unit 14 and the matrix is selected, such that the control device 11 can access the applicable parameters stored in the correlation table. In the present exemplary method, the parameters are as shown in Table 1.

TABLE 1
Parameters of the method

| | | |
|---|---|---|
| matrix temperature Tₘ | 125° | C. |
| substrate temperature Tₛ | 10° | C. |
| pressure pₛ | 5 | bar |
| gas temperature T_{g} | 60° | C. |
| deposition time t_{d} | 10 | min |

By starting the process, the pressure in the sublimation chamber 3 is decreased by means of the pressure adjustment unit 4 until the desired pressure pₛ has been reached. Meanwhile, the temperature of the matrix is increased by means of the heating unit 8 until the predetermined matrix temperature Tₘ is reached. Also the substrate 5 is cooled by means of the cooling unit 7 to predetermined substrate temperature Tₛ in order to guarantee re-sublimation of sublimated matrix on the sample. After an equilibration phase, i.e., after Tₛ, Tₘ, and pₛ have been reached, the shutter 12 is brought into the open position, allowing sublimated matrix 1 to reach the substrate 2.

The matrix 1 is re-sublimating on the cooled substrate 5. After a pre-set deposition time t_{d}, the shutter 12 is closed again, such that further matrix 1 is prevented from reaching the substrate 2. The sublimation chamber 3 is brought back to atmospheric pressure.

After opening the shutter 12, the matrix container 6 is removed from the recess 13 and a vapor generation unit 10 filled with a liquid 24, which is an acid in the present example, is inserted into the recess 13. The shutter 12 is closed again and the sublimation chamber 3 is reassembled by closing the lid 20.

Under control of the control device 11, hot air at temperature T_{g} is blown into the sublimation chamber 3 using the gas supply unit 9, allowing for recrystallization of the matrix 1 that has been previously deposited in the substrate 2. Additionally, the liquid in the vapor generation unit 10 is heated by means of the heating unit 8.

After the temperature T_{g} has been reached, the shutter 12 is opened, such that acidic vapor is introduced to the sublimation chamber 3. After a pre-set recrystallization time, the acidic vapor is pumped from the sublimation chamber 3 by means of the pressure adjustment unit 4.

The substrate 2 carrying the sample to be analyzed is now covered by a layer of recrystallized matrix and can further proceed to MALDI-MSI analysis.

FIG. 4 is a schematic cross sectional view of the bottom part of an apparatus according to a second exemplary embodiment of the present invention. The difference as compared to the first embodiment described above is that a second heating unit 25 with a second recess 26 is provided, where the vapor generation unit 10 is placed. This means that the matrix container 6 and the vapor generation unit 10 are not interchangeable.

The upper part of the apparatus of the second embodiment is identical to the first embodiment and therefore is not shown in FIG. 2.

In addition, the shutter 12 is adapted such that the matrix container 6 and the vapor generation unit 10 can be selectably covered and uncovered.

Furthermore, a vapor generation temperature sensor 27 is provided which is used to measure and control the temperature applied to the vapor generation unit 10 in a closed-loop.

Apart from these differences, the second embodiment is essentially identical as compared to the first embodiment. Thus, the further features will not be reiterated for the sake of conciseness. The second embodiment provides the advantage that the matrix container 6 and the vapor generation unit 10 do not need to be exchanged manually.

An apparatus according to a third exemplary embodiment of the present invention, which is not shown in any of the drawings, does not include the gas supply unit 9 and the vapor generation unit 10 with their respective control means. In all other aspects, the third embodiment is essentially identical to the first embodiment. Using the apparatus of the third embodiment, no recrystallization of the matrix 1 deposited onto the substrate 2 can be performed, but all other advantages of the invention can be exploited similarly.

### LIST OF REFERENCE NUMERALS

1 Sublimated matrix
2 Substrate
3 Sublimation chamber
4 Pressure adjustment unit
5 Substrate holder
6 Matrix container
7 Cooling unit
8 Heating unit
9 Gas supply unit
10 Vapor generation unit
11 Control device
12 Shutter
13 Recess
14 Input unit
15 Pressure sensor
16 Matrix temperature sensor
17 Substrate temperature sensor
18 Drive unit
19 Opening
20 Lid
21 Chamber body
22 Motor unit
23 Drive rod
24 Liquid
25 Second heating unit
26 Second recess
27 Vapor generation temperature sensor

1. An apparatus for depositing sublimated matrix (1) to a substrate (2), the apparatus comprising
a sublimation chamber (3)
a pressure adjustment unit (4) adapted to adjust the gas pressure (pₛ) inside the sublimation chamber (3),
a substrate holder (5) being arranged inside the sublimation chamber (3) and being adapted to hold the substrate (2), wherein a predetermined temperature (Tₛ) can be applied to the substrate (2) by means of a a cooling unit (7),
a heating unit (8) comprising a matrix container (6), the matrix container (6) being arranged inside the sublimation chamber (3) and at a distance to the substrate holder (5), wherein a predetermined temperature (Tₘ) can be applied to the matrix (1) by means of the heating unit (8), and
a control device (11) being operably connected to the pressure adjustment unit (4), to the heating unit (7), and optionally to the cooling unit (8),
characterized in that the apparatus comprises a gas supply unit (9) adapted to introduce a stream of heated gas at a temperature (T_{g}) of above 50° C., preferably of above 100° C., into the sublimation chamber (3).

2. The apparatus according to claim 1, wherein the apparatus comprises a vapor generation unit (10) adapted to introduce a vaporized substance, in particular an acidic substance, into the sublimation chamber (3).

3. The apparatus according to claim 2, wherein the vapor generation unit (10) is heatable by means of the heating unit (8).

4. The apparatus according to claim 3, wherein the heating unit (8) comprises a recess (13) into which the matrix container (6) and the vapor generation unit (10) can be interchangeably inserted.

5. The apparatus according to claim 1, wherein the apparatus comprises a shutter (12), the shutter (12) being adapted to be switched between a first position and a second position, wherein in its first position the shutter (12) prevents sublimated matrix (1) from being deposited on the substrate (2), and wherein in its second position the shutter (12) allows sublimated matrix (1) to be deposited on the substrate (2).

6. The apparatus according to claim 5, wherein the shutter (12) in its first position substantially completely covers the recess (13) of the heating unit (7).

7. The apparatus according to claim 1, wherein the control device (11) is adapted to adjust the gas pressure (pₛ) inside the sublimation chamber (3), as well as the temperature (Tₘ) applied to the matrix (1) and the temperature (Tₛ) applied to the substrate (2) on the basis of a correlation table, which correlation table contains a predetermined list of matrices (M₁, M₂, . . . Mₙ) each matrix in the correlation table being assigned with a sublimation chamber pressure (p_{s,1}, p_{s,2}, . . . , p_{s,n}), matrix temperature (T_{m,1}, T_{m,2}, . . . , T_{m,n}) and substrate temperature (T_{s,1}, T_{s,2}, . . . , T_{s,n}).

8. The apparatus according to claim 7, wherein the control device (11) comprises an input unit (14), where a matrix material (M₁, M₂, . . . , Mₙ) contained in the correlation table can be selected.

9. The apparatus according to claim 7, wherein the control device (11) is operably connected to the shutter (12).

10. The apparatus according to claim 7, wherein a pressure sensor (15) is provided in the sublimation chamber (3) which is operably connected to the control device (11), such that a closed-loop control of the gas pressure (pₛ) inside the sublimation chamber (3) can be performed.

11. The apparatus according to claim 7, wherein a matrix temperature sensor (16) is provided which is adapted to measure the temperature of the matrix (1) and which is operably connected to the control device (11), such that a closed-loop control of the matrix temperature (Tₘ) can be performed.

12. The apparatus according to claim 7, wherein a substrate temperature sensor (17) is provided which is adapted to measure the temperature of the substrate (2) and which is operably connected to the control device (11), such that a closed-loop control of the substrate temperature (Tₛ) can be performed.

13. The apparatus according to claim 1, wherein the distance (d) between substrate holder (5) and matrix container (6) is adjustable, preferably by means of a drive unit (18).

14. The apparatus according to claim 7, and according to claim 13, wherein the drive unit (18) is operably connected to the control device (11), wherein each matrix in the correlation table is additionally assigned with a distance (d₁, d₂, . . . , dₙ), and wherein the distance (d) between substrate holder (5) and matrix container (6) is adjusted on the basis of the correlation table.

15. The apparatus according to claim 7, wherein the gas supply unit (9) is operably connected to the control device (11), wherein each matrix in the correlation table is additionally assigned with a temperature (T_{g,1}, T_{g,2}, . . . , T_{g,n}) of the heated gas, and wherein the temperature of the heated gas (T_{g}) is adjusted on the basis of the correlation table.

16. A method depositing a sublimated matrix (1) to a substrate (2), the method comprising the following steps:
a. positioning the matrix (1) and the substrate (2) at a distance from each other in a sublimation chamber (3),
b. controlling the gas pressure (pₛ) inside the sublimation chamber to a first gas pressure level (p_{s,a}), wherein the first gas pressure level (p_{s,a}) is below atmospheric pressure,
c. heating the matrix (1) to a predetermined matrix temperature (Tₘ) and cooling the substrate (2) to a predetermined substrate temperature (Tₛ), wherein the matrix temperature (Tₘ) is above the matrix sublimation point (T_{sub}) at the first gas pressure level (p_{s,a}), and wherein the substrate temperature (Tₛ) is below the matrix material sublimation point (T_{sub}) at the first gas pressure level (p_{s,a}), such that at least part of the matrix (1) is sublimated and subsequently re-sublimated on the substrate (2),
d. introducing a stream of heated gas at a temperature (T_{g}) of above 50° C., preferably of above 100° C., into the sublimation chamber (3).

17. The method according to claim 16, wherein step (d) additionally comprises introducing a vaporized substance into the sublimation chamber (3).

18. The method according to claim 17, wherein the vaporized substance is an acidic substance.

19. The method according to claim 16, wherein the matrix temperature (Tₘ) in step (b) is between 100° C. and 200° C., and/or wherein the substrate temperature (Tₛ) in step (b) is between 10° C. and 20° C.

20. The method according to claim 16, wherein the first gas pressure (p_{s,a}) is below 200 mbar.

21. The method according to claim 16, wherein the gas pressure (pₛ) inside the sublimation chamber in step (d) is controlled to a second gas pressure (p_{s,b}), wherein the second gas pressure (p_{s,b}) is between 900 mbar and 1100 mbar, preferably at atmospheric pressure.

22. The method according to claim 16, wherein in step (c) sublimated matrix (1) is prevented from being deposited on the substrate (2) during an equilibration phase, wherein during the equilibration phase the matrix (1) is heated to and/or kept at the predetermined matrix temperature (Tₘ).

23. The method according to claim 22, wherein the equilibration phase is followed by a deposition phase, wherein in the deposition phase sublimated matrix (1) is allowed to be deposited on the substrate (2), and wherein the first gas pressure (p_{s,a}), the matrix temperature (Tₘ), and the substrate temperature (Tₛ) are substantially constant during the deposition phase.

24. The method according to claim 16, wherein in step (c) sublimated matrix (1) is allowed to be deposited on the substrate (2) for at least 5 min, preferably for between 10 min to 60 min.
